(19) United States
(12) Patent Application Publication
(10) Pub. No.: US 2023/0197566 A1
(43) Pub. Date: Jun. 22, 2023

(54) Semiconductor Die, Heat Spreader, Semiconductor Package, Semiconductor Device, and Methods

(71) Applicant: Intel Corporation, Santa Clara, CA (US)

(72) Inventors: Bernd WAIDHAS, Pettendorf (DE); Wolfgang MOLZER, Ottobrunn (DE); Peter BAUMGARTNER, Muenchen (DE); Thomas WAGNER, Regelsbach (DE); Joachim SINGER, Neubiberg (DE); Klaus HEROLD, Muenchen (DE); Michael LANGENBUCH, Muenchen (DE)

(21) Appl. No.: 17/644,802

(22) Filed: Dec. 17, 2021

(51) Int. Cl. H01L 23/433; H01L 23/473; H01L 23/40; H01L 21/48

(52) U.S. Cl. CPC H01L 23/433; H01L 21/4871; H01L 23/473; H01L 23/4012; H01L 2023/4068

(57) ABSTRACT

A semiconductor die is provided. The semiconductor die includes a plurality of transistors arranged at a front side of a semiconductor substrate and an electrically conductive structure and a trench extending from a backside of the semiconductor substrate into the semiconductor substrate. A length of the trench is equal or larger than a lateral dimension of the semiconductor substrate.

### BACKGROUND

3D integration is a general trend for High Performance Compute (HPC) applications. A significant challenge hereby is the heat dissipation in an active die/die stack and an effective cooling to prevent overheating or a thermal runaway. In semiconductor packages known from other systems the main thermal path is through a Thermal Interface Material (TIM) connected to a backside of the die stack and to a package or system heat spreader. Heat generated in an active area of each die in the stack accumulates on the main thermal path to the backside of the die stack. However, the main thermal path limits total power dissipation capabilities and a number of semiconductor dies in a stack. Thus, there may be a need to increase a heat dissipation of a semiconductor die stack and/or a semiconductor die.

### BRIEF DESCRIPTION OF THE FIGURES

Some examples of apparatuses and/or methods will be described in the following by way of example only, and with reference to the accompanying figures, in which

FIG. 1 shows a cross-sectional view of a semiconductor die;

FIG. 2 shows a cross-sectional view of a heat spreader;

FIG. 3 shows a cross-sectional view of semiconductor package;

FIG. 4 shows a cross-sectional view of a semiconductor device;

FIG. 5a and FIG. 5b show different trenches extending from a backside of the semiconductor substrate into the semiconductor substrate;

FIG. 6a shows a cross-sectional top view and FIGS. 6b-6c show different cross-sectional side views of an example of a semiconductor device;

FIG. 7 shows a cross-sectional side view of another example of a semiconductor device and a cross-sectional top view of the semiconductor stack of the other example of the semiconductor device;

FIG. 8 shows a cross-sectional side view of another example of a semiconductor device and a cross-sectional top view of the semiconductor stack of the other example of the semiconductor device;

FIG. 9 shows a cross-sectional view of another example of a semiconductor device;

FIGS. 10a-10e show different examples of stacking semiconductor dies with different trenches.

FIG. 11 shows a table comprising electronic coolants;

FIG. 12 shows an example of a method for forming a semiconductor die;

FIG. 13 shows an example of a method for forming a semiconductor package;

FIG. 14 shows an example of a method for forming a heat spreader; and

FIG. 15 shows a computing device.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of the group A and B”. The same applies for combinations of more than 2 Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

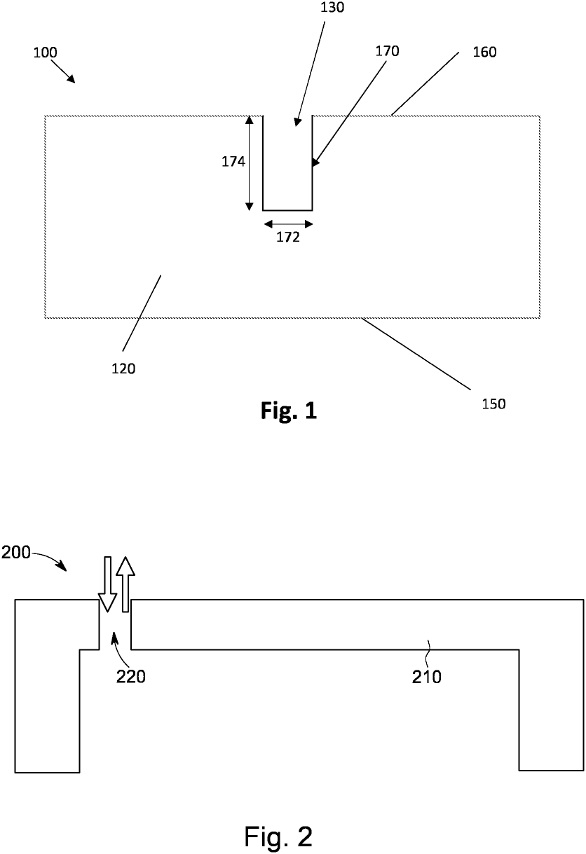

FIG. 1 shows a cross-sectional view of a semiconductor die 100. The semiconductor die 100 comprises a plurality of transistors (not shown) arranged at a front side 150 of a semiconductor substrate 120. Further, the semiconductor die 100 comprises a trench 130 extending from a backside 160 of the semiconductor substrate 120 into the semiconductor substrate 120. A length of the trench 130 is equal or larger than a lateral dimension of the semiconductor substrate 120.

The trench 130 increases an exposed area at the backside 160 of the semiconductor substrate 120. A surface of the trench 130 may define a cooling area 170 of the trench. For example, the cooling area 170 may increase with an increasing cross section of the trench 130. The cooling area 170 may be a surface of the semiconductor substrate 120 formed by the trench 130, which is in contact with the cooling fluid. For example, the trench 130 can be used to lead/guide a cooling fluid. For example, the trench 130 may be a groove extending from the backside 160 of the semiconductor substrate 120 into the semiconductor substrate 120.

The trench 130 can be used for liquid or immersion cooling of the semiconductor die 100, especially in between different dies, e.g., the semiconductor die 100 and a further die attached to the backside 160 of the semiconductor substrate 120 of the semiconductor die 100.

For example, the trench 130 may form a part of a (fluid) channel, which can be used to conduct a cooling fluid, e.g., water, ethylene glycol, propylene glycol, combinations thereof, etc. The channel for the cooling fluid may be formed by the trench 130 and another channel structure, e.g., a structure attached to the backside 160 of the semiconductor die 120, e.g., a further die, a lead frame, a package substrate, etc.

By using the trench 130 to form a (fluid) channel an improved heat dissipation for high performance applications, for 3D die stacking heterogeneous assemblies, etc. can be achieved. The improved heat dissipation caused by the trench 130 may lead to an enhanced cooling, which can improve the performance of devices for high performance applications or use cases for 3D die stacking heterogeneous assemblies. For example, the trench 130 can be used to improve a heat dissipation for a high-performance three-dimensional integrated circuit (3D IC) face-to-face-based packaging technology.

The semiconductor die 100 may be a processor die (e.g. a Central Processing Unit CPU die, a Graphics Processing Unit GPU die, a microcontroller die or a Digital Signal Processor DSP die), a memory die, a Micro-Electro-Mechanical System MEMS die, a transceiver die or any other semiconductor die.

The semiconductor die 100 may comprise a plurality of contact interface structures (e.g. contact pads) for electrically connecting the semiconductor die 100 to a package structure. For example, a plurality of solder balls (e.g. ball grid array BGA) may be arranged on the contact interface structures of the semiconductor die 100. The plurality of solder balls may be soldered to a plurality of contact interface structures (e.g. contact pads) of the package structure. The semiconductor die 100 may comprise a wiring layer stack formed on the semiconductor substrate 120. The package structure may comprise or may be a package substrate, a redistribution layer or a lead frame.

The semiconductor die 100 may comprise a plurality of bonding interface structures (e.g., metallic contacts) for hybrid bonding the semiconductor die 110 to a further semiconductor die or package structure. The bonding interface structures may be located on the same surface as the trench 130, the backside 160 of the semiconductor substrate 120. The bonding interface structures can be used to electrically connect the semiconductor die 100 with the further semiconductor die or package structure.

The semiconductor substrate 120 may comprise or may be composed of any type of substrate. For example, the semiconductor substrate 120 may comprise or may be composed of a single crystal of a material which may include, but is not limited to, silicon, germanium, silicon-germanium, germanium-tin, silicon-germanium-tin, or a group III-V compound semiconductor material. The semiconductor substrate 120 may be a bulk substrate or may be part of a Semiconductor-On-Insulator (SOI) substrate.

A dimension of the trench 130, and thus a dimension of the cooling area 170 can be adjusted to the semiconductor die 100 and/or a used cooling fluid. For example, the cooling area 170 may be increased for a semiconductor die 100 with high power electronic circuits and/or for a cooling fluid with a decreased thermal conductivity. For example, the cooling area 170 may be decreased for a semiconductor die 100 with low power electronic circuits and/or for a cooling fluid with an increased heat absorption coefficient.

In an example, a width of the trench 172 may be at least 10 µm (at least 50 µm, at least 100 µm or at least 500 µm). In an example, a depth of the trench 174 may be at least 10 µm (at least 50 µm, at least 100 µm or at least 500 µm).

The trench 130 may have a length equal to a lateral dimension, e.g., a length or a width, of the semiconductor die 100. In an example, the trench 130 may extend from a first edge of the semiconductor substrate 120 to an opposing second edge of the semiconductor substrate 120. This way, a cooling fluid can reach the trench 130 from two sides of the semiconductor substrate 120, which may ease a supply of the cooling fluid. For example, the cooling fluid may flow from a first side of the semiconductor substrate 120 to an opposing second side of the semiconductor substrate 120 through a channel formed by the trench 130 and another channel structure. Adjacent to the first side may be a first cavity for feeding the cooling fluid and adjacent to the second side may be a second cavity for draining the cooling fluid. This way, the cooling fluid can flow through the trench 130 in an eased way by feeding/draining the cooling fluid to the first cavity and the second cavity.

In an example, the semiconductor substrate 120 may further comprise a plurality of trenches. By using a plurality of trenches a size of a cooling area 170 formed by the plurality of trenches is increased. Each trench 130 of the plurality of trenches may extend from a first edge of the semiconductor substrate 120 to an opposing second edge of the semiconductor substrate 120. This way, each trench 130 of the plurality of trenches can be feed/drained by the same first cavity and the same second cavity. Thus, a feeding/draining of the cooling fluid to/from the plurality of trenches can be eased.

Alternatively, the trench 130 may have a length larger than a lateral dimension, e.g., a length, of the semiconductor substrate 120. In an example, the trench 130 may extend in a meandering pattern along the backside 160 of the semiconductor substrate 120. By the meandering pattern a length of the trench 130 (and thus the cooling area 170) can be increased, such that a flow time of the cooling for flowing through the trench 130 is increased (and a contact for the fluid contacting the cooling area 170), which may increase a heat dissipation by the cooling fluid. For example, the trench 130 may form a first opening at a first edge of the semiconductor substrate 120 and a second opening at a second edge of the semiconductor substrate 120. Alternatively, the trench 130 may be embedded in the backside 160 of the semiconductor substrate 120, such that the trench 130 cannot be seen from a side view of the semiconductor die 100. For this case, the fluid may be feed/drained from top of the semiconductor substrate 120, e.g., by attaching a feeding pipe to a first end and a second end of the trench 130.

In an example, the semiconductor die 100 may further comprise a supply recess. A supply recess’ cross section is larger than a trench’s cross section. For example, the supply recess may be formed on a backside 160 of the semiconductor substrate 120 adjacent to the trench 130, e.g., the supply recess may form a part of the (fluid) channel for the cooling fluid. For example, the feeding pipe may be positioned above the supply recess, which is formed on a backside 160 of the semiconductor substrate 120 and adjacent to the trench 130. Because of the increased supply recess’ cross section a positioning/arranging of the feeding pipe can be eased. The feeding pipe may be guided through the further channel structure used to form the (fluid) channel.

For example, the feeding pipe may comprise a plurality of sub-feeding pipes, each sub-feeding pipe may feed one supply recess/trench 130. Thus, the feeding pipe may support a plurality of parallel fluid channels by the plurality of sub-feeding pipes. The plurality of parallel fluid channel may be connected together by the feeding pipe, e.g., a common feed. The common feed may be attached to opposite site trenches 130, e.g., drain channels.

In an example, a depth of the supply recess may be equal to a depth of the trench 130. This way, the trench 130 and the supply recess can be formed by the same process, e.g., an etching process, especially with the same process parameters (e.g., an etching time). Thus, a manufacturing of the supply recess and the trench 130 can be eased. Since the depth of the trench 130 and the supply recess may be equal, both may differ in a width and/or length (a supply recess’ width/length is larger than a trench’s width/length). In an example, a width of the supply recess may be at least 20 µm (at least 50 µm, at least 100 µm or at least 500 µm).

In an example, the trench 130 or the plurality of trenches may cover at least 5%, or at least 10%, or at least 15% of the backside 160 of the semiconductor substrate 120. Thus, a heat dissipation can be adjusted to a desired value, e.g., by designing the meandering pattern of the trench 130 or a number of the plurality of trenches in a way to achieve a minimum required coverage of the backside 160 of the semiconductor substrate 120.

In an example, a thickness of the semiconductor substrate 120 may be at most 750 µm or at most 500 µm or at most 400 µm or at most 300 µm.

A cross section’s shape of the trench 130 and the optional supply recess and thus the (fluid) channel may depend on a process of forming the trench 130 and the optional supply recess. For example, the process of forming the trench 130/supply recess may be chosen depending on a required cooling area 170. The cooling area 170 can be increased by an increased cross-section of the trench 130/supply recess. The fluid channels can be created, e.g., by an etching process, such like anisotropic etching, isotropic etching, of the backside 160 of the semiconductor die 100 to create the trench 130 and optional the supply recess. In an example, a trench’s cross section may have a tapered shape. The trench 130 may be shaped like a V-groove (e.g., by anisotropic etching), a U-groove ((e.g., by (Deep) Reactive Ion Etching ((D)RIE))), etc. In an example, the supply recess’ cross section may have a tapered shape. The supply recess’ cross section may be shaped like a V or a U and may have a circular/elliptical shape in a top view. The shape of the trench 130/supply recess depends on an etching process and/or on an orientation of the semiconductor substrate 120.

The created trench 130 or the supply recess may be attached to a feeding pipe for feeding the cooling fluid. Further, an electrical connection between the semiconductor die 100 and a further semiconductor die acting as channel structure to form the (fluid) channel can be generated by use of a bonding interface structure, e.g., by direct bonding (DB) interconnect technology, such like hybrid bonding.

The term “direct bonding” may be used to include metal-to-metal bonding techniques (e.g., copper-to-copper bonding, or other techniques in which the DB contacts of opposing DB interfaces are brought into contact first, then subject to heat and compression) and hybrid bonding techniques (e.g., techniques in which the DB dielectric of opposing DB interfaces are brought into contact first, then subject to heat and sometimes compression, or techniques in which the DB contacts and the DB dielectric of opposing DB interfaces are brought into contact substantially simultaneously, then subject to heat and compression). In such techniques, the DB contacts and the DB dielectric at one DB interface are brought into contact with the DB contacts and the DB dielectric at another DB interface, respectively, and elevated pressures and/or temperatures may be applied to cause the contacting DB contacts and/or the contacting DB dielectrics to bond. In some embodiments, this bond may be achieved without the use of intervening solder or an anisotropic conductive material, while in some other embodiments, a thin cap of solder may be used in a DB interconnect to accommodate planarity, and this solder may become an intermetallic compound (IMC) in the DB region during processing. In some embodiments, this bond may be achieved by use of copper-copper bonding. DB interconnects may be capable of reliably conducting a higher current than other types of interconnects; for example, some conventional solder interconnects may form large volumes of brittle IMCs when current flows, and the maximum current provided through such interconnects may be constrained to mitigate mechanical failure.

A DB dielectric may include one or more dielectric materials, such as one or more inorganic dielectric materials. For example, a DB dielectric may include silicon and nitrogen (e.g., in the form of silicon nitride); silicon and oxygen (e.g., in the form of silicon oxide); silicon, carbon, and nitrogen (e.g., in the form of silicon carbonitride); carbon and oxygen (e.g., in the form of a carbon-doped oxide); silicon, oxygen, and nitrogen (e.g., in the form of silicon oxynitride); aluminum and oxygen (e.g., in the form of aluminum oxide); titanium and oxygen (e.g., in the form of titanium oxide); hafnium and oxygen (e.g., in the form of hafnium oxide); silicon, oxygen, carbon, and hydrogen (e.g., in the form of tetraethyl orthosilicate (TEOS)); zirconium and oxygen (e.g., in the form of zirconium oxide); niobium and oxygen (e.g., in the form of niobium oxide); tantalum and oxygen (e.g., in the form of tantalum oxide); and combinations thereof.

A DB contact may include a pillar, a pad, or other structure. The DB contacts may have a same structure at both DB interfaces (a backside 160 of the semiconductor substrate 120 of the semiconductor die 100 and a front side of a further semiconductor die), or the DB contacts at different DB interfaces may have different structures. For example, in some embodiments, a DB contact in one DB interface may include a metal pillar (e.g., a copper pillar), and a complementary DB contact in a complementary DB interface may include a metal pad (e.g., a copper pad) recessed in a dielectric. A DB contact may include any one or more conductive materials, such as copper, manganese, titanium, gold, silver, palladium, nickel, copper and aluminum (e.g., in the form of a copper aluminum alloy), tantalum (e.g., tantalum metal, or tantalum and nitrogen in the form of tantalum nitride), cobalt, cobalt and iron (e.g., in the form of a cobalt iron alloy), or any alloys of any of the foregoing (e.g., copper, manganese, and nickel in the form of manganin). In some embodiments, the DB dielectric and the DB contacts of a DB interface may be manufactured using low-temperature deposition techniques (e.g., techniques in which deposition occurs at temperatures below degrees Celsius, or below degrees Celsius), such as low-temperature plasma-enhanced chemical vapor deposition (PECVD).

More details and aspects are mentioned in connection with the examples described below. The example shown in FIG. 1 may comprise one or more optional additional features corresponding to one or more aspects mentioned in connection with the proposed concept or one or more examples described below (e.g., FIGS. 2 - 15).

FIG. 2 shows a cross-sectional view of a heat spreader 200. The heat spreader 200 for a semiconductor device (e.g., a semiconductor device comprising the semiconductor die as described with reference to FIG. 1) comprises a heat spreading structure 210 attachable to a package structure. The heat spreading structure 210 comprises an opening 220 for conducting a cooling fluid. The heat spreader 200 can be used to improve a heat dissipation and/or an assembling of a semiconductor device comprising a semiconductor die as described with reference to FIG. 1. For example, the opening 220 of the heat spreader 200 for conducting the cooling fluid can be used to position a feeding pipe for a semiconductor device. The heat spreader 200 may be positioned above the semiconductor die, such that the opening 220 of the heat spreader 200 is positioned above a part of a trench/supply recess of the semiconductor die. This way, the feeding pipe can be positioned on the semiconductor by guiding the feeding pipe trough the opening 220 of the heat spreader 200.

The heat spreader 200 may comprise or may be composed of any suitable conductive material. For example, the heat spreader 200 may comprise or may be composed of a metal, such like copper, aluminum, etc.

In an example, the opening 220 may have a maximal cross section dimension (e.g. a diameter) of at least 500 µm (or at least 1 mm or at least 2 mm). In an example, the opening 220 may have maximal cross section dimension (e.g. a diameter) of at most 5 mm (or at most 2 mm or at most 1 mm). The diameter of the opening 220 may depend on a usage of the opening 220, e.g., if the opening 220 is used for feeding and draining the cooling fluid, for feeding or draining the cooling fluid or a feeding pipe comprising a plurality of sub-feeding pipes.

In an example, the heat spreader 200 may further comprise an interface for attaching a feeding pipe, such that the cooling fluid can flow by use of the feeding pipe through the opening 220. This way, an attachment of the feeding pipe can be eased. Further, also an arranging of the feeding pipe to the semiconductor die can be eased.

Optionally or alternatively, the heat spreader 200 may comprise a further opening. In an example, the heat spreading structure 210 may comprise a first opening for feeding the cooling fluid and a second opening for draining the cooling fluid. For example, the first opening can be the opening 220. This way, the heat spreader 200 can be used to form a first cavity and a second cavity for feeding/draining the cooling fluid. For example, the first opening 220 may be used to feed the cooling fluid into the first cavity formed below the first opening 220 and the second opening may be used to drain the cooling fluid from the second cavity formed below the second opening.

In an example, the heat spreader 200 may further comprise a sealing structure for attaching the heat spreading structure 210 to a package structure. This way, an attachment of the heat spreader 200 can be eased, such that a manufacturing process of a semiconductor device comprising the heat spreader 200 may be improved. The sealing structure may be any suitable material. In an example, the sealing structure may comprise or may be composed of solder. The sealing structure may ensure a hermetic seal between the package substrate and the heat spreader 200. Thus, a leakage of the cooling fluid can be omitted.

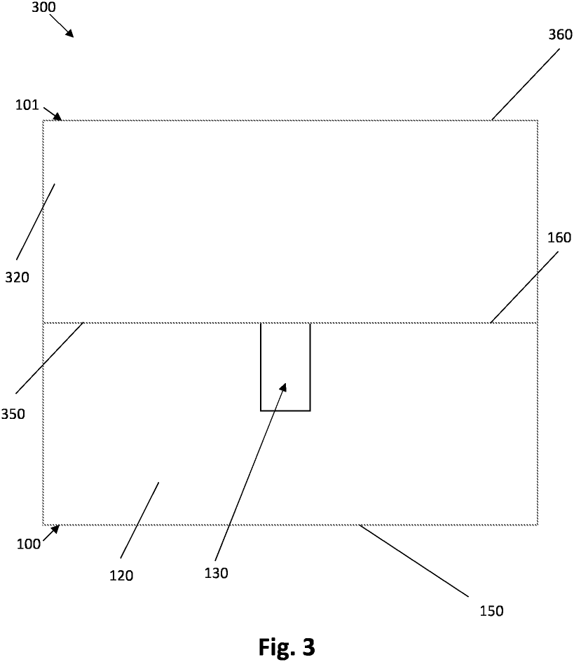

More details and aspects are mentioned in connection with the examples described above and/or below. The example shown in FIG. 2 may comprise one or more optional additional features corresponding to one or more aspects mentioned in connection with the proposed concept or one or more examples describe above (e.g., FIG. 1) and/or below (e.g., FIGS. 3 -15).

FIG. 3 shows a cross-sectional view of semiconductor package 300. The semiconductor package 300 comprises a first semiconductor die 100 comprising a plurality of transistors arranged at a front side 150 of the first semiconductor die 100 and a second semiconductor die 101. Further, a trench 130 is formed in a surface of a backside 160 of a first semiconductor substrate 120 of the first semiconductor die 100 and/or (in a surface of a front side 350 or a backside 360 of) a second semiconductor substrate 320 of the second semiconductor die 101. A length of the trench 130 is equal or larger than a lateral dimension of the first semiconductor substrate 120 and/or the second semiconductor substrate 320. Further, the first semiconductor die 100 is attached to the second semiconductor die 101 so that the trench 130 is located between the first semiconductor die 100 and the second semiconductor die 101. Thus, the trench 130 forms with a surface of second semiconductor die 101, e.g., the front side 350 of the second semiconductor substrate 320, a (fluid) channel. Even if the trench 130 is only depicted as formed in the backside 160 of the first semiconductor substrate 120 in FIG. 3, the trench 130 could also be formed instead in the front side 350 or if a third semiconductor die is attached to the second semiconductor die 101 in the backside 360 of the second semiconductor substrate 320 of the second semiconductor die 101.

For example, the second semiconductor die 101 may be passive die, which is designed to improve a heat dissipation in a semiconductor package, e.g., the semiconductor package 300. To achieve this purpose the second semiconductor die 101 is attached to the first semiconductor die 100. If the first semiconductor die 100 does not comprise a trench 130 the second semiconductor die 101 comprises the trench 130. Further, the second semiconductor die 101 may not comprise any active electronic circuitries. This way, a (fluid) channel can be formed by use of the first semiconductor die 100 and the second semiconductor die 101 comprising the trench 130. Thus, a heat dissipation can be increased, which may decrease a temperature of the semiconductor package 300 during operation.

The trench 130 may increase the dissipation of the semiconductor package 300. For example, a cooling fluid can be conducted through the (fluid) channel formed by the trench 130 and the front side 350 of the second semiconductor substrate 320.

In an example, the backside 160 of the first semiconductor die 100 may be attached to the front side 350 of the second semiconductor die 101. In this case, the trench 130 is either formed in the backside 160 of the first semiconductor die 100 or in the front side 350 of the second semiconductor die 101. Optionally or alternatively, both the first semiconductor die 100 and the second semiconductor die 101 comprises a trench 130. For example, a first trench 130 is formed in the backside 160 of the first semiconductor die 100 and a second trench is formed in the front side 350 of the second semiconductor die 101. This way, the cooling area can be increased, which may increase a dissipation of the semiconductor package 300.

In an example, the first semiconductor die 100 may be a semiconductor die as described above, e.g., with reference to FIG. 1. In an example, the second semiconductor die 101 may be a semiconductor die as described above, e.g., with reference to FIG. 1. Thus, also the second semiconductor die 101 may be an active semiconductor die.

In an example, the first semiconductor die 100 or the second semiconductor die 101 may comprise a plurality of holes extending through the respective semiconductor substrate 120, 320 and wherein each hole of the plurality of holes faces a part of the trench 130 or a supply recess of the second semiconductor die 101 or the first semiconductor die 100. The plurality of holes can be utilized to guide a feeding pipe. For example a first hole of the plurality of holes may be used to guide a feeding pipe for feeding a cooling fluid and a second hole of the plurality of ports may be used to guide a feeding pipe for draining the cooling fluid. Alternatively, the first semiconductor die 100 or the second semiconductor die 101 may comprise only one hole formed through the respective semiconductor substrate 120, 320. This one hole may be used to guide the feeding pipe for feeding and draining the cooling fluid. By use of the plurality of holes an arrangement of a feeding pipe can be improved.

In an example, a first semiconductor die’s cross section may be larger than a second semiconductor die’s cross section. The first semiconductor die 100 comprises the trench 130 formed in the surface of the backside 160 of the semiconductor substrate 120 of the first semiconductor die 100. Further, the semiconductor package 300 may comprise a supply channel arranged beside the second semiconductor die 101 and on top of the first semiconductor die 100 die or a supply recess of the first semiconductor die. The supply channel comprises an opening, which faces the trench 130 of the first semiconductor die 100. This way, forming a plurality of holes through the second semiconductor die 101 can be omitted. Thus, the manufacturing of the semiconductor package 300 may be eased. Further, semiconductor dies 100, 101 with different cross-sections can be combined in a semiconductor package 300, still providing an improved heat dissipation achieved by the trench 130.

For example, the supply channel may comprise or may be composed of an insulating material. In an example, the supply channel may be formed in at least one of a mold material and a dielectric material. For example, the mold material or the dielectric material may be formed on top of the first semiconductor die 100 and besides the second semiconductor die 101. The supply channel can be formed in the mold material or the dielectric material after forming the respective material on top of the semiconductor die 100 and besides the second semiconductor die 101. Thus, a hole (opening) for a feeding pipe can be formed through the mold material on the dielectric material.

In an example, the supply channel may comprise a metal ring embedded in an electrically insulating material. This way, a contact between the cooling fluid and the electrical insulating material, e.g., the mold material or the dielectric material, can be avoided. Thus, chemical interactions between the cooling fluid and the electrically insulating material can be omitted. The metal ring may comprise or may be composed of any suitable material chemically inert to the cooling fluid.

In an example, the first semiconductor die 100 may be attached to the second semiconductor die 101 by hybrid bonding or may be made by hybrid bonding. For example, a use of hybrid bonding can ensure a hermetic sealed (fluid) channel. This way, the (fluid) channel can be formed in an eased way.

In an example, the semiconductor package 300 may further comprise a package substrate. Further, the first semiconductor die 100 may be attached with the front side 150 of the first semiconductor substrate 120 to the package substrate. As described above in FIG. 1 the first semiconductor die 100 may comprise a plurality of contact interface structures (e.g. contact pads) for electrically connecting the semiconductor die 100 to the package structure. A plurality of solder balls (e.g. ball grid array BGA) may be arranged on the contact interface structures of the semiconductor die 100. The plurality of solder balls may be soldered to a plurality of contact interface structures (e.g. contact pads) of the package structure. The package structure may comprise or may be a package substrate, a redistribution layer or a lead frame.

In an example, the semiconductor package 300 may further comprise a heat spreader as described above, e.g., with reference to FIG. 2. The heat spreader may be attached to the backside 360 of the second semiconductor die 101 or a further semiconductor die located on the second semiconductor die 101 (e.g., if the second semiconductor die 101 comprises a trench 130 in a backside 360 of the second semiconductor substrate 320). This way, a heat dissipation of the semiconductor package 300 may be improved by the heat spreader. Further, an arrangement of the feeding pipe can be increased by the opening of the heat spreader.

In an example, the heat spreader may be further attached to a package structure. This way, a mechanical stability of the semiconductor package 300 can be increased. In an example, the heat spreader may be attached to the backside 360 of the second semiconductor die 101 or the further semiconductor die by a thermal backside interface material. The thermal backside interface material may contact the backside 360 of the second semiconductor die 101 or the further semiconductor die with the heat spreader. This way, a heat dissipation can be further improved, since the thermal backside interface material can also dissipate heat from the semiconductor package 300.

In an example, the semiconductor package 300 may further comprise a sealing interface material. The sealing interface material may contact two opposing sides of the semiconductor package 300 with the heat spreader. Thus, the heat spreader can form two cavities with the semiconductor package 300, the thermal backside interface material, the sealing interface material and the package structure. These two cavities can be utilized for feeding and draining the cooling fluid.

The first semiconductor substrate 120 and/or the second semiconductor substrate 320 may comprise or may be composed of any type of substrate. For example, the first semiconductor substrate 120 and/or the second semiconductor substrate 320 may comprise or may be composed of a single crystal of a material which may include, but is not limited to, silicon, germanium, silicon-germanium, germanium-tin, silicon-germanium-tin, or a group III-V compound semiconductor material. The first semiconductor substrate 120 and/or the second semiconductor substrate 320 may be a bulk substrate or may be part of a semiconductor-on-insulator SOI substrate.

The first semiconductor die 100 and/or the second semiconductor die 101 may be a processor die (e.g. a CPU die, a GPU die, a microcontroller die or a DSP die), a memory die, a MEMS die, a transceiver die or any other semiconductor die.

The semiconductor package 300 may comprise further semiconductor dies. The semiconductor package 300 may comprise a plurality of contact interface structures (e.g. contact pads) for electrically connecting the semiconductor package 300 to an external component (e.g. a circuit board). The plurality of contact interface structures may be located on a surface of the semiconductor package structure (e.g. the package substrate). A plurality of solder balls (e.g. ball grid array BGA) may be arranged on the contact interface structures of the semiconductor package 300.

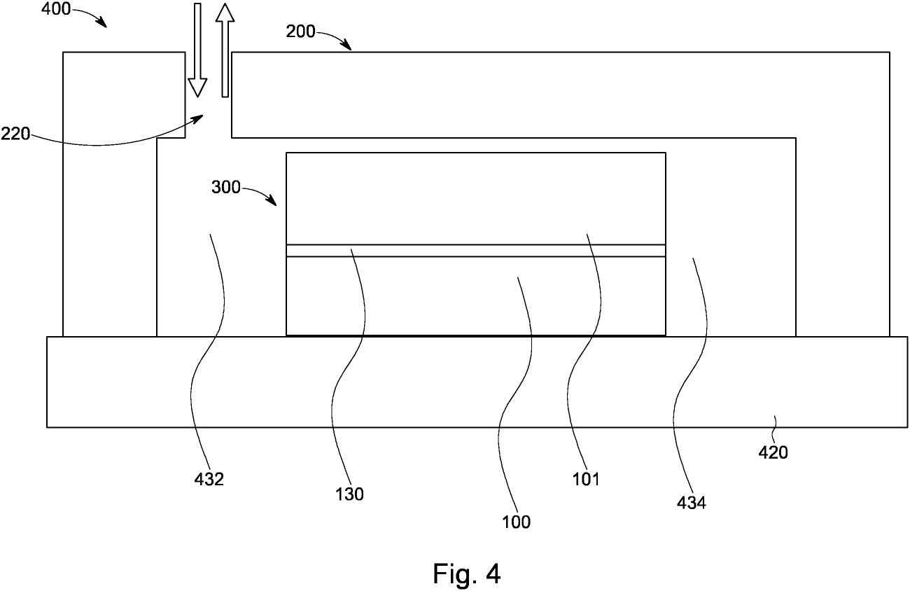

More details and aspects are mentioned in connection with the examples described above and/or below. The example shown in FIG. 3 may comprise one or more optional additional features corresponding to one or more aspects mentioned in connection with the proposed concept or one or more examples describe above (e.g., FIGS. 1 - 2) and/or below (e.g., FIGS. 4 - 15).

FIG. 4 shows a cross-sectional view of a semiconductor device 400 (note, the cross-sectional view runs along a cutting plane in which a trench 130 is present). The semiconductor device 400 comprises a semiconductor package 300 as described above, e.g., with reference to FIG. 3 and a package substrate 420. The first semiconductor die 100 or the second semiconductor die 101 (of the semiconductor package 300) is attached with the respective front side of the first semiconductor substrate or the second semiconductor substrate to the package structure 420. Further, the semiconductor device 400 comprises a heat spreader 200 as described above, e.g., with reference to FIG. 2, attached to the package structure 420. Thus, the semiconductor device 400 may have an improved heat dissipation characteristic, caused by a trench 130 of the first semiconductor die 100 or the second semiconductor die 101. Even if the trench 130 is only depicted as formed in the backside 160 of the first semiconductor substrate 120 of the first semiconductor die 100 in FIG. 4, the trench 130 could also be formed instead in the front side of the second semiconductor substrate of the second semiconductor die 101. Even if it is only depicted that the first semiconductor die 100 is attached to the package structure 420 in FIG. 4, the second semiconductor die 101 could also be attached to the package structure 420. The package structure 420 may comprise or may be a package substrate, a redistribution layer or a lead frame.

In an example, the package structure 420 may comprise a metallic conduct structure on a front side of the package structure 420 facing the semiconductor package 300 and the heat spreader 200. For example, the metallic conduct structure can be used to attach the heat spreader 200 to the package structure 420. Thus, an attachment of the heat spreader 200 may be eased. In an example, the heat spreader 200 may be attached to the metallic conduct structure of the package structure 420 by use of a sealing structure. For example, the sealing structure of the heat spreader 200 and/or the metallic conduct structure may comprise or may be composed of a metallic material, e.g., a solder. For example, the sealing structure and metallic conduct structure may comprise equal material.

In an example, the semiconductor device 400 may further comprise a semiconductor die contact solder structure for contacting the first semiconductor die 100 or the second semiconductor die 101 with the package structure 420, an underfill to underfill the contact structure and a sealing structure covering an edge of the underfill structure. The sealing structure may embed the underfill. For example, the sealing structure may surround the underfill. Thus, the cooling fluid cannot contact the underfill, which prevents from undesired chemical interactions between the underfill and the cooling fluid. This way, a chemical stability of the semiconductor device 400, especially of the underfill and thus of the contract soldier structure can be increased. For example, the sealing structure may be any suitable material, which is chemically inert to the cooling fluid.

In an example, the sealing structure may be attached to the metallic conduct structure. This way, a mechanically stability between the sealing structure and the package structure 420 may be increased.

In an example, the semiconductor device 400 may further comprise a thermal backside interface material. The thermal backside interface material may contact a backside of the semiconductor package 300 with the heat spreader 200. The thermal backside interface material may contact the backside 360 of the second semiconductor die 101 or the further semiconductor die with the heat spreader 200. This way, a heat dissipation can be further improved, since the thermal backside interface material can also dissipate heat from the semiconductor package 300.

In an example, the semiconductor device 400 may further comprise a sealing interface material. The sealing interface material may contact two opposing sides of the semiconductor package 300 with the heat spreader 200. Thus, the heat spreader 200 can form two cavities with the semiconductor package 300, the thermal backside interface material, the sealing interface material and the package structure 420. These two cavities can be utilized for feeding and draining the cooling fluid.

In an example, the sealing interface material and the heat spreader 200 may form a first cavity 432 and a second cavity 434 besides the semiconductor package 300. The first cavity 432 may be for feeding a cooling fluid and the second cavity 434 may be for draining the cooling fluid, such that the cooling fluid flows through a first opening 220 of the heat spreader 200 in the first cavity 432, through the trench 130 in the second cavity 434 and through a second opening (not shown) of the heat spreader 200 out of the second cavity 434. Thus, a feeding/draining of the cooling fluid to/from a trench 130 can be eased, especially for a plurality of trenches.

The semiconductor device 400 may be a processor (e.g. CPU, GPU or DSP), a memory or any other integrated circuit.

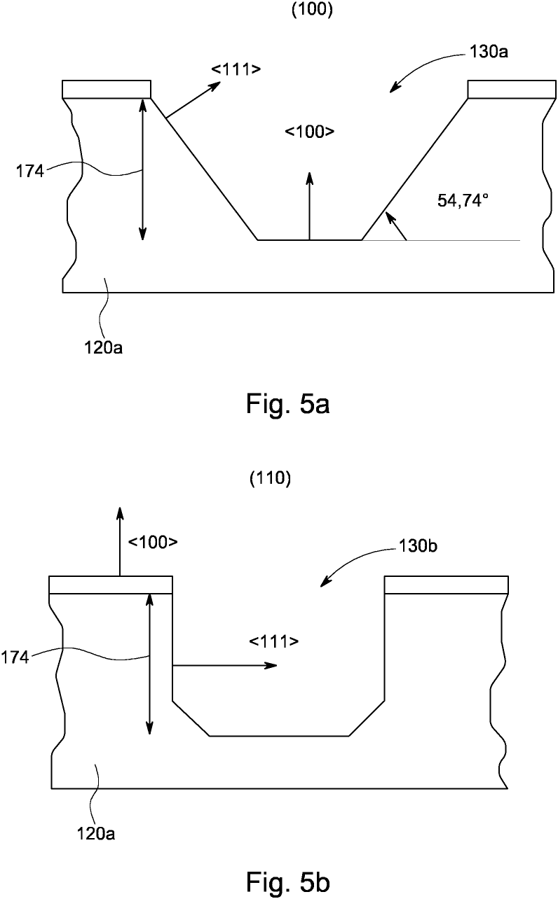

More details and aspects are mentioned in connection with the examples described above and/or below. The example shown in FIG. 4 may comprise one or more optional additional features corresponding to one or more aspects mentioned in connection with the proposed concept or one or more examples describe above (e.g., FIGS. 1 - 3) and/or below (e.g., FIGS. 5 - 15).

FIG. 5a and FIG. 5b show different trenches 130a, 130b extending from a backside of the semiconductor substrate 120a, 120b into the semiconductor substrate 120a, 120b. The semiconductor substrate 120a has an orientation of (100) and the semiconductor substrate 120b has an orientation of (110). The trench 130a, 130b is formed by an anisotropic etching process. Thus, the shape of the trench 130a, 130b depends on the orientation of the semiconductor substrate 120a, 120b. As can be seen the trench 130a has rather a V-shape, whereas the trench 130b has rather a U-shape, caused by the different orientation of the semiconductor substrates 130a, 130b. A depth of the trench 130a, 130b depends on a process time of the etching process. For a longer etching process the depth of the trench 130a, 130b is increased.

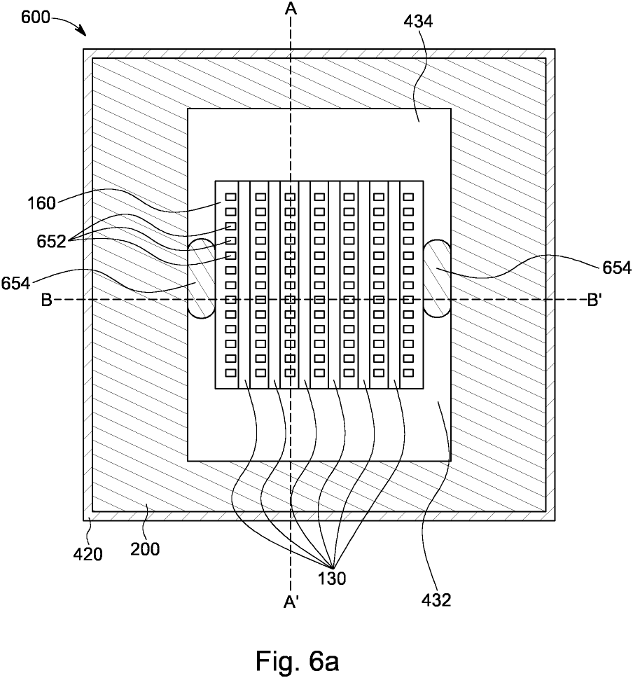

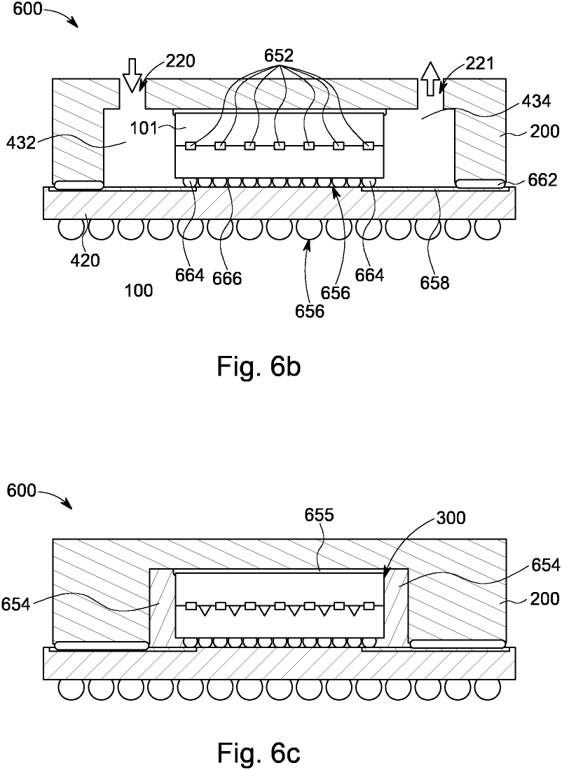

More details and aspects are mentioned in connection with the examples described above and/or below. The example shown in FIG. 5 may comprise one or more optional additional features corresponding to one or more aspects mentioned in connection with the proposed concept or one or more examples describe above (e.g., FIGS. 1 - 4) and/or below (e.g., FIGS. 6 - 15).

FIG. 6a shows a cross-sectional top view and FIGS. 6b-6c show different cross-sectional side views of an example of a semiconductor device 600. The cross-sectional top view in FIG. 6a runs along a cutting plane at the top of a first semiconductor die. The cross-sectional (side) view in FIG. 6b runs along the line A-A′. The cross-sectional (side) view in FIG. 6c runs along the line B-B′.

FIG. 6a shows a plurality of trenches 130 extending from a backside 160 of a first semiconductor substrate into the first semiconductor substrate. Each trench 130 of the plurality of trenches extends from a first edge of the first semiconductor substrate to an opposing second edge of the first semiconductor substrate. Besides the trenches a bonding interface structure 652 may be formed. The bonding interface structure 652 may be used for bonding the first semiconductor die to a second semiconductor die, e.g., by hybrid bonding. Further the semiconductor device 600 may comprise a sealing interface structure 654. The sealing interface structure 654 may contact two opposing sides of the semiconductor package (compiling the first semiconductor die and a second semiconductor die) with the heat spreader 200. Further the sealing interface structure 654 may be in contact with a thermal backside interface material, e.g., see FIG. 6c. Thus, two cavities 432 and 434 are formed, which are comprised by the semiconductor device 600.

The plurality of trenches 130 form with the second semiconductor die (fluid) channels for conducting a cooling fluid. Thus, a cooling of the semiconductor device 600 can be increased. To form the (fluid) channels the first semiconductor die and the second semiconductor die are stacked. For example, the first semiconductor die and the second semiconductor die may be stacked by use of hybrid bonding, which may improve a sealing of the (fluid) channels. The plurality of trenches 130 can be formed in the first semiconductor die (as shown in FIG. 6a and FIG. 6c), in the second semiconductor die or both semiconductor dies.

In FIG. 6b the first semiconductor die 100 and the second semiconductor die 101 can be seen. The second semiconductor die 101 is stacked on top of the first semiconductor die 100. Both semiconductor dies may be stacked by hybrid bonding using the bonding interface structure 652. As described above the bonding interface structure 652 may be a metallic structure such like a pillar, a pad, or another structure, which enables the hybrid bonding of the first semiconductor die 100 to the second semiconductor die 101.

Further the semiconductor device 600, especially the first semiconductor die 100, may comprise a contract interface structure. For example, a plurality of solder balls 656 (e.g. ball grid array BGA) may be arranged on the contact interface structures of the first semiconductor die 100. The plurality of solder balls 656 may be used to electrically contact the first semiconductor die 100 to the package substrate 420.

The semiconductor device 600 may also comprise a metallic conduct structure 658. The metallic conduct structure 658 comprise metal or may be a Metal/Cupper-plane. The metallic contact structure 658 may be attached to the package substrate 420. Further, the metallic contact structure 658 may be used to attach the heat spreader 200 to the package structure 420. The heat spreader 200 of the semiconductor device 600 may comprise a sealing structure 662 to attach the heat spreader 200 to the package substrate 420, especially to the metallic conduct structure 658. The sealing structure 662 may comprise or may be made of any material suitable for soldering. Thus, by soldering the sealing structure 662 to the metallic conduct structure 658 a hermetic seal can be formed.

Further, the semiconductor device 600 may comprise a solder ring seal 664 contacted to the front side of the first semiconductor die 100. The solder ring seal 664 may embed the plurality of solder balls 656 and shield the plurality of solder balls and an underfill 666 from the cooling fluid. Thus, a chemical interaction between the plurality of solder balls 656 and/or the underfill 666 can be avoided.

The package structure 420 may comprise a plurality of contact interface structures (e.g. contact pads) for electrically connecting the package structure 420 to an external component (e.g. a circuit board). The plurality of contact interface structures may be located on a surface of the semiconductor package structure (e.g. the package substrate). A plurality of solder balls 657 (e.g. ball grid array BGA) may be arranged on the contact interface structures of the package structure 420.

FIG. 6c shows optional seals between the semiconductor package 300 and the heat spreader 200. The optional seals may be the sealing interface structure 654 and the thermal backside interface material 655. By use of these both optional seals two cavities can be formed as described with reference to FIG. 6a. Thus, openings formed in the heat spreader 200 can be utilized to feed and/or drain the cooling fluid. For example, a first opening 220 may be utilized for feeding the cooling fluid into a first cavity 432. From the first cavity 432 the cooling fluid may flow through the trenches 130 in the second cavity 434. Optionally, if no terminally backside interface material 655 contracts the semiconductor package 300 with the heat spreader 200 the cooling fluid may flow between the backside of the second semiconductor die and the heat spreader 200. From the second cavity 434 the cooling fluid may be drained through the second opening 221.

Both seals 654, 655 may be utilized to conduct the fluid flow through the trenches 130. Thus, the fluid flow can be directed by use of the seals 654, 655.

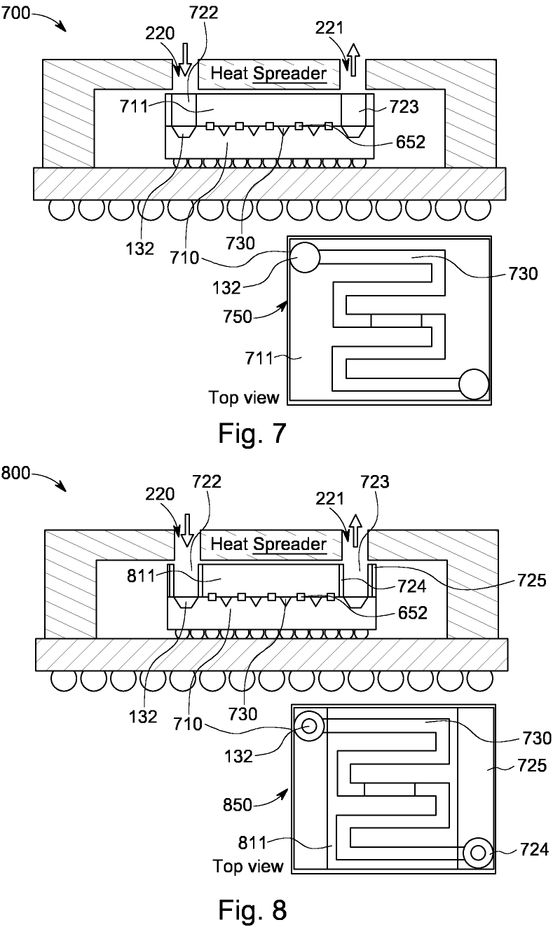

More details and aspects are mentioned in connection with the examples described above and/or below. The example shown in FIG. 6 may comprise one or more optional additional features corresponding to one or more aspects mentioned in connection with the proposed concept or one or more examples describe above (e.g., FIGS. 1 - 5) and/or below (e.g., FIGS. 7 - 15).

FIG. 7 shows a cross-sectional side view of another example of a semiconductor device 700 and a cross-sectional top view of the semiconductor stack 750 of the other example of the semiconductor device 700. The semiconductor device 700 comprises a first semiconductor die 710 and a second semiconductor die 711. The first semiconductor die 710 comprises a trench 730 which is formed in the backside of the first semiconductor die 710. The second semiconductor die 711 is attached to the first semiconductor die 710, e.g., by bonding (e.g., by hybrid bonding), e.g., by use of a bonding interface structure 652. Thus, a (fluid) channel for conducting a cooling fluid is formed by the trench 730 (and the supply recess 132) and a front side of the second semiconductor die 711.

The second semiconductor die 711 comprises a first hole 722 and a second hole 723, which are arranged below the first opening 720 and the second opening 721 of the heat spreader, respectively. The first opening 720 may be for feeding the cooling fluid and the second opening 721 may be for draining the cooling fluid. The holes 722, 723 of the second semiconductor die 711 may be arranged above the two supply recesses 132. Thus the cooling fluid can flow through the first opening 220, the first hole 722 in the second semiconductor die 711, the trench 730, the second hole 723 in the second semiconductor die 711 and the second opening 221. This way, the cooling of the semiconductor device 700 can be improved, since the heat dissipation can be improved by the cooling fluid flowing between the first semiconductor die 710 and the second semiconductor die 711.

The holes 722, 723 may be through silicon cooling pipes 722, 723. A feeding pipeline may be led through the through silicon cooling pipes 722, 723. Thus, a heat pipe concept using the trench 730 can be realized. By forming the through silicon cooling pipes 722, 723 and feeling/draining the cooling fluid may be improved. For example, the feeding pipe can be attached to the backside of the second semiconductor die 711 or to an interface of the heat spreader for feeding/draining the cooling fluid.

The trench 730 may have a V-shape and can be formed in the first semiconductor die 710, the second semiconductor die 711 or in both semiconductor dies 710, 711.

As can be seen in the top view the trench 730 extends in a meandering pattern from first supply recess 132 to a second supply recess. Thus, a cooling area can be spread over the backside of the first semiconductor die 710.

By use of the trench 730 an active cooling between the first semiconductor die 710 and the second semiconductor die 711 can be achieved. Further, no hermetic substrate, bottom flip chip connect or an integrated heat spreader to package substrate seal may be required.

More details and aspects are mentioned in connection with the examples described above and/or below. The example shown in FIG. 7 may comprise one or more optional additional features corresponding to one or more aspects mentioned in connection with the proposed concept or one or more examples describe above (e.g., FIGS. 1 - 6) and/or below (e.g., FIGS. 8 - 15).

FIG. 8 shows a cross-sectional side view of another example of a semiconductor device 800 and a cross-sectional top view of the semiconductor stack 850 of the other example of the semiconductor device 800. The semiconductor device 800 comprises a first semiconductor die 710 and a second semiconductor die 811. The first semiconductor die 710 comprises a trench 730 which is formed in the backside of the first semiconductor die 710. The second semiconductor die 811 is attached to the first semiconductor die 710, e.g., by bonding (e.g., by hybrid bonding), e.g., by use of a bonding interface structure 652. Thus, a (fluid) channel for conducting a cooling fluid is formed by the trench 730 (and the supply recess 132) and a front side of the second semiconductor die 811.

A cross-section of the first semiconductor die 710 is larger than a cross section of the second semiconductor die 811. On top of the first semiconductor die 710 and besides the second semiconductor die 811 an electrically insulating material 725 may be formed. The electrically insulating material 725 may be a mold material or the dielectric material. Holes 822, 823 may be formed in the electrical insulating material 724 for feeding/draining the cooling fluid. To avoid a chemical interaction between the cooling fluid and the electrically insulating material 725 a metal ring 724 may be formed inside of the electrical insulating material 725. Thus, chemical interaction between the cooling fluid and the electrical insulating material 724 can be omitted.

The holes 822, 823 of the electrically insulating material 724 may be arranged above the two supply recesses 132. Thus the cooling fluid can flow through the first opening 220, a first hole 822, the trench 730, a second hole 723 and the second opening 221. This way, the cooling of the semiconductor device 800 can be improved, since the heat dissipation can be improved by the cooling fluid flowing between the first semiconductor die 710 and the second semiconductor die 811.

The holes 822, 823 may be through mold cooling pipes 822, 823. A feeding pipeline may be led through the through mold cooling pipes 822, 823. Thus, a heat pipe concept using the trench 730 can be realized. By forming the through mold cooling pipes 822, 823 and feeling/draining the cooling fluid may be improved. For example, the feeding pipe can be attached to the backside of the second semiconductor die 711 or to an interface of the heat spreader for feeding/draining the cooling fluid.

The trench 730 may have a V-shape and can be formed in the first semiconductor die 710, the second semiconductor die 811 or in both semiconductor dies 710, 811.

Further, by use of the electrically insulation material no through silicon cooling pipe may be required. Also semiconductor dies with different cross-section/sizes can be stacked. Thus, a manufacturing process can be eased.

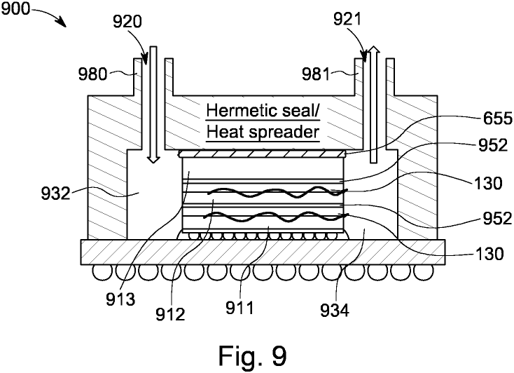

More details and aspects are mentioned in connection with the examples described above and/or below. The example shown in FIG. 8 may comprise one or more optional additional features corresponding to one or more aspects mentioned in connection with the proposed concept or one or more examples describe above (e.g., FIGS. 1 - 7) and/or below (e.g., FIGS. 9 - 15).

FIG. 9 shows a cross-sectional view of another example of a semiconductor device 900. The semiconductor device 100 comprises a first semiconductor device 911, a second semiconductor device 112 and a third semiconductor device 913. The third semiconductor device 913 is stacked on the second semiconductor device 912, which is stacked the first semiconductor device 911. For example, the semiconductor die’s 911, 912, 913 may be stacked by hybrid bonding, e.g., by use of bonding interface structures 952. The first semiconductor die 111 and the second semiconductor die 912 comprises each trench 130. The trench extends from a first edge to an opposing second edge of the respective semiconductor die 911, 912. Thus, a cooling fluid can flow from a first cavity 932 through the trenches 130 and a second cavity 934. This may increase a cooling by dissipating heat toward the second cavity 921 (as indicated by the curved arrows).

The cooling fluid can be fed in the first cavity 932 through a first opening 920 of the heat spreader and may be drained from the second cavity 934 through a second opening 921 of the heat spreader. The first opening 920 and the second opening 921 comprises each an interface structure 980, 981 for attaching a feeding pipe.

Further the semiconductor device 100 comprises a thermal backside interface material 655 for forming the first cavity 932 and the second cavity 934. A sealing interface structure for forming the first cavity 932 and the second cavity 934 is not shown in FIG. 9.

Note, even if FIG. 9 (or other examples) show a specific number of semiconductor dies, the number of semiconductor dies of the semiconductor package/semiconductor device is not restricted. Further, each semiconductor die may comprise at least one trench formed in the backside of the semiconductor die. If the semiconductor die is a passive die, the semiconductor die may comprise two trenches formed in opposing surfaces of the semiconductor die, e.g., a front side and a backside surface. Thus, the semiconductor package of the semiconductor device can be designed in any desired way, e.g., to achieve a required heat dissipation.

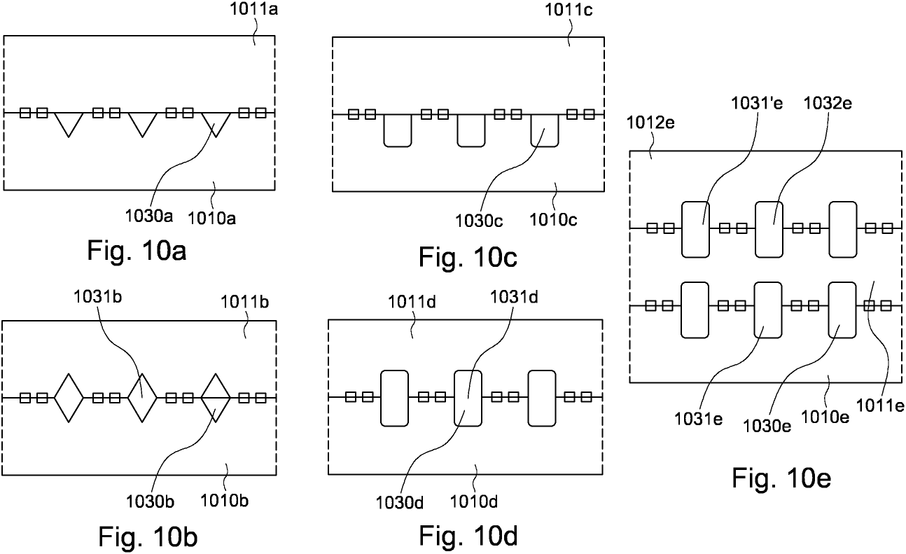

More details and aspects are mentioned in connection with the examples described above and/or below. The example shown in FIG. 9 may comprise one or more optional additional features corresponding to one or more aspects mentioned in connection with the proposed concept or one or more examples describe above (e.g., FIGS. 1 - 8) and/or below (e.g., FIGS. 10 - 15).

FIGS. 10a-10e show different examples of stacking semiconductor dies 1010a, 1011a, 1010b, 1011b, 1010c, 1011c, 1010d, 1011d, 1010e, 1011e with different trenches 1030a, 1030b, 1031b, 1030c, 1030d, 1031d, 1030e, 1031e, 1031′e, 1032e.

FIG. 10a shows a first semiconductor die 1010a and a second semiconductor die 1011a stacked on top of the first semiconductor die 1010a. The first semiconductor die 1010a comprises a trench 1030a for conducting a cooling fluid. The trench 1030a has a V-shape.

FIG. 10b shows a first semiconductor die 1010b and a second semiconductor die 1011b stacked on top of the first semiconductor die 1010b. The first semiconductor die 1010b and the second semiconductor die 1011b comprise a trench 1030b or 1031b for conducting a cooling fluid. Both trenches 1030b, 1031b faces each other. Alternatively, both trenches 1030b, 1031b can be arranged in a way that, they only partially overlap each other. The trenches 1030b, 1031b have a V-shape.

FIG. 10c shows a first semiconductor die 1010c and a second semiconductor die 1011c stacked on top of the first semiconductor die 1010c. The first semiconductor die 1010c comprises a trench 1030a for conducting a cooling fluid. The trench 1030c has a U-shape.

FIG. 10d shows a first semiconductor die 1010d and a second semiconductor die 1011d stacked on top of the first semiconductor die 1010d. The first semiconductor die 1010d and the second semiconductor die 1011d comprise a trench 1030d or 1031d for conducting a cooling fluid. Both trenches 1030d, 1031d faces each other. Alternatively, both trenches 1030d, 1031d can be arranged in a way that, they only partially overlap each other. The trenches 1030d, 1031d have a U-shape.

FIG. 10e shows a first semiconductor die 1010e, a second semiconductor die 1011e stacked on top of the first semiconductor die 1010e and a third semiconductor 1012e die stacked on top of the second semiconductor die 1011e. The first semiconductor die 1010e, the second semiconductor die 1011e and the third semiconductor die 1012e comprise a trench 1030e, 1031e, 1031e or 1032e for conducting a cooling fluid. The second semiconductor die may be a passive die, e.g., a semiconductor die for cooling the semiconductor die stack, and thus may comprise trenches in opposing surfaces, e.g., a front side and a backside. The trench 1030e faces the trench 1031e and the trench 1031e faces the trench 1032e. Alternatively, the trenches 1030e, 1031e, 1031e, 1032e can be arranged in a way that, they only partially overlap each other. The trenches 1030e, 1031e, 1031e, 1032 have a U-shape.

The V-shaped trenches 1030a, 1030b, 1031b may be formed by, e.g., anisotropic etching. The U-shaped trenches 1030c, 1030d, 1031d, 1030e, 1031e, 1031′e, 1032 may be formed by, e.g., (D)RIE.

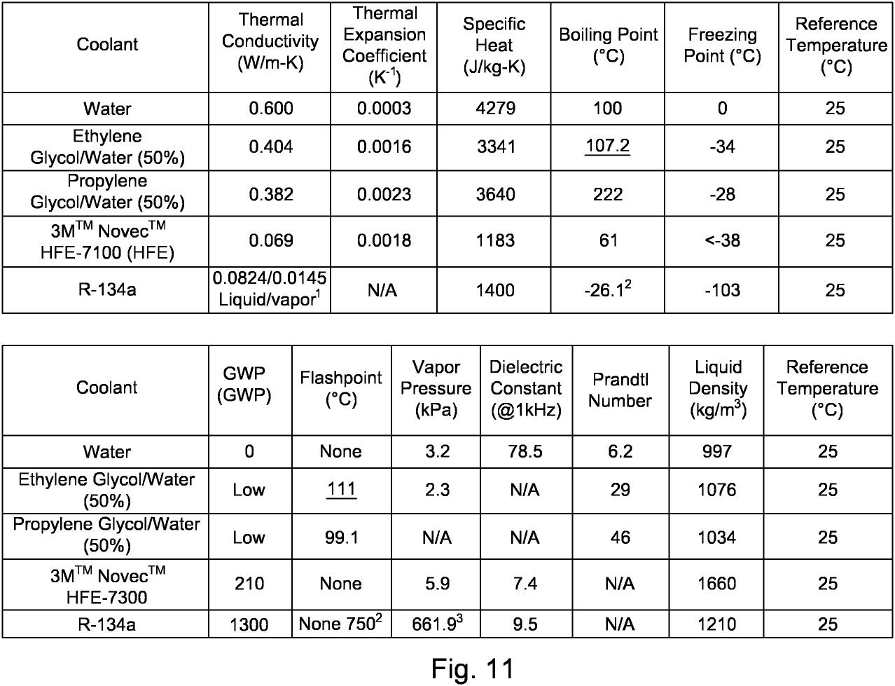

More details and aspects are mentioned in connection with the examples described above and/or below. The example shown in FIG. 10 may comprise one or more optional additional features corresponding to one or more aspects mentioned in connection with the proposed concept or one or more examples describe above (e.g., FIGS. 1 - 9) and/or below (e.g., FIGS. 11 - 15).

FIG. 11 shows a table comprising electronic coolants. As has been described above any suitable fluid can be utilized as cooling fluid in combination with the proposed semiconductor as described above, e.g., with reference to FIG. 1, the proposed semiconductor package as described above, e.g., with reference to FIG. 3 and/or the semiconductor device as described above, e.g., with reference to FIG. 4.

As can be seen from FIG. 11 different electronic coolants can be utilized in combination with a semiconductor die comprising a trench. As described above the trench (e.g., a cross-section, a length, a number of a plurality of trenches) can be adjusted to a desired electronic coolant and/or a heat generation of a semiconductor die/semiconductor package. This way, use cases for 3D stacking can be increased by an improved heat dissipation due to the active cooling between semiconductor dies by the trench in a semiconductor package.

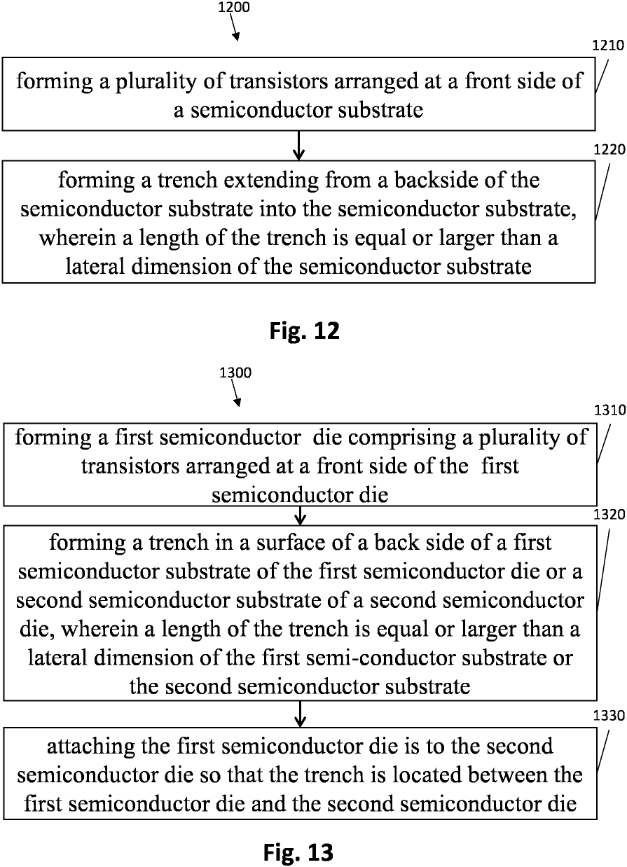

More details and aspects are mentioned in connection with the examples described above and/or below. The example shown in FIG. 11 may comprise one or more optional additional features corresponding to one or more aspects mentioned in connection with the proposed concept or one or more examples describe above (e.g., FIGS. 1 - 10) and/or below (e.g., FIGS. 12-15).

FIG. 12 shows an example of a method 1200 for forming a semiconductor die. The method 1200 comprises forming 1210 a plurality of transistors arranged at a front side of a semi-conductor substrate and forming 1220 a trench extending from a backside of the semiconductor substrate into the semiconductor substrate, wherein a length of the trench is equal or larger than a lateral dimension of the semiconductor substrate. The method 1200 can be used to form a semiconductor die as described above, e.g., with reference to FIG. 1.

In an example, the trench may be formed by an etching process. For example, a shape/cross-section of the trench may depend on an etching process and/or on an orientation of the semiconductor substrate of the semiconductor die. For example, a V-shape can be formed by use of an anisotropic etching process. For example, a U-shape can be formed by use of a (D)RIE.

In an example, the etching process may be an anisotropic etching process.

More details and aspects are mentioned in connection with the examples described above and/or below. The example shown in FIG. 12 may comprise one or more optional additional features corresponding to one or more aspects mentioned in connection with the proposed concept or one or more examples describe above (e.g., FIGS. 1 - 11) and/or below (e.g., FIGS. 13 - 15).

FIG. 13 shows an example of a method 1300 for forming a semiconductor package. The method 1300 comprises forming 1310 a first semiconductor die comprising a plurality of transistors arranged at a front side of the first semiconductor die and forming 1320 forming a trench in a surface of a backside of a first semiconductor substrate of the first semiconductor die or a second semiconductor substrate of a second semiconductor die, wherein a length of the trench is equal or larger than a lateral dimension of the first semi-conductor substrate or the second semiconductor substrate. Further, the method 1300 comprises attaching 1330 the first semiconductor die to the second semiconductor die so that the trench is located between the first semiconductor die and the second semiconductor die. This way, a (fluid) channel for the cooling fluid can be formed. The method 1300 can be used to form a semi-conductor package as described above, e.g., with reference to FIG. 3.

In an example, attaching 1330 the first semiconductor die to the second semiconductor die may comprise hybrid bonding or may be hybrid bonding. This way, a hermetic sealed (fluid) channel can be achieved.

In an example, a first semiconductor die’s cross section may be larger than a second semi-conductor die’s cross section. The first semiconductor die may comprise the trench formed in the surface of the backside of the semiconductor substrate of the first semiconductor die. Further, the method 1300 may comprise arranging a supply channel besides the second semiconductor die and on top of the first semiconductor die. The supply channel may comprise an opening, which faces the trench of the first semiconductor die. Thus, a semiconductor package as described above, e.g., with reference to FIG. 8, can be formed.

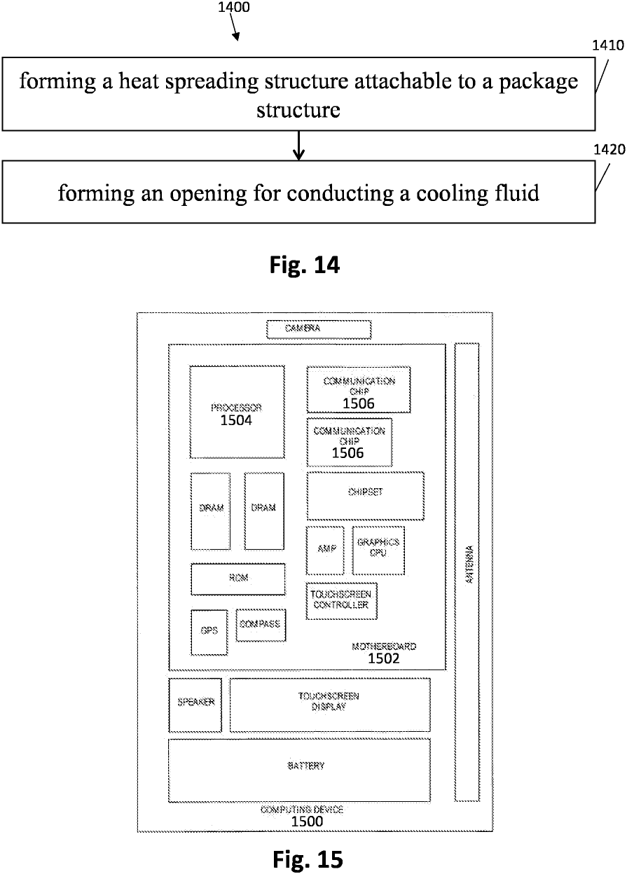

More details and aspects are mentioned in connection with the examples described above and/or below. The example shown in FIG. 13 may comprise one or more optional additional features corresponding to one or more aspects mentioned in connection with the proposed concept or one or more examples describe above (e.g., FIGS. 1 - 12) and/or below (e.g., FIGS. 14-15).

FIG. 14 shows an example of a method 1400 for forming a heat spreader. The method 1400 comprises forming 1410 a heat spreading structure attachable to a package structure and forming 1420 an opening for conducting a cooling fluid. This way, a heat as described above, e.g., with reference to FIG. 2, can be formed.

In an example, the method 1400 may further comprise forming a sealing structure for attaching the heat spreader to a package structure. This way, a hermetic sealed cavity can be achieved, e.g., for feeding/draining a cooling fluid.

More details and aspects are mentioned in connection with the examples described above and/or below. The example shown in FIG. 14 may comprise one or more optional additional features corresponding to one or more aspects mentioned in connection with the proposed concept or one or more examples describe above (e.g., FIGS. 1 - 13) and/or below (e.g., FIG. 15).

FIG. 15 shows a computing device 1500. The computing device 1500 houses a board 1502. The board 1502 may include a number of components, including but not limited to a processor 1504 and at least one communication chip 1506. A semiconductor device as described above (e.g., with respect to FIG. 4) may be the processor 1504, the graphics CPU or a memory device as shown in FIG. 15, for example. For example, the processor 1504, the graphics CPU or a memory device may comprise a semiconductor die as described above, e.g., with reference to FIG. 1. For example, the processor 1504, the graphics CPU or a memory device may comprise a semiconductor stack as described above, e.g., with reference to FIG. 3.

The processor 1504 is physically and electrically coupled to the board 1502. In some embodiments the at least one communication chip 1506 is also physically and electrically coupled to the board 1502. In further embodiments, the communication chip 1506 is part of the processor 1504.

Depending on its applications, computing device 1500 may include other components that may or may not be physically and electrically coupled to the board 1502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). The communication chip 1506 enables wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1500 may include a plurality of communication chips 1506. For instance, a first communication chip 1506 may be dedicated to shorter range wireless communications such as Wi-Fi and Bluetooth and a second communication chip 1506 may be dedicated to longer range wireless communications such as GPS, EDGE, GPRS, CDMA, WiMAX, LTE, Ev-DO, and others.

The processor 1504 of the computing device 1500 includes an integrated circuit die packaged within the processor 1504. In some embodiments, the integrated circuit die of the processor includes one or more devices that are assembled in an ePLB or eWLB based P0P package that that includes a mold layer directly contacting a substrate, in accordance with embodiments. The term “processor” may refer to any device or portion of a device that processes electronic data from registers and/or memory to transform that electronic data into other electronic data that may be stored in registers and/or memory.

The communication chip 1506 also includes an integrated circuit die packaged within the communication chip 1506. In accordance with another embodiment, the integrated circuit die of the communication chip includes one or more devices that are assembled in an ePLB or eWLB based P0P package that that includes a mold layer directly contacting a substrate, in accordance with embodiments.

More details and aspects are mentioned in connection with the examples described above. The example shown in FIG. 15 may comprise one or more optional additional features corresponding to one or more aspects mentioned in connection with the proposed concept or one or more examples described above (e.g., FIGS. 1 - 14).

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

An example (e.g., example 1) relates to a semiconductor device, comprising a plurality of transistors arranged at a front side of a semiconductor substrate and a trench extending from a backside of the semiconductor substrate into the semiconductor substrate, wherein a length of the trench is equal or larger than a lateral dimension of the semiconductor substrate.

Another example (e.g., example 2) relates to a previously described example (e.g., example 1) wherein a width of the trench is at least 10 µm.

Another example (e.g., example 3) relates to a previously described example (e.g., one of the examples 1-2) wherein a depth of the trench is at least 10 µm.

Another example (e.g., example 4) relates to a previously described example (e.g., one of the examples 1-3) wherein the trench extends in a meandering pattern along the backside of the semiconductor substrate.

Another example (e.g., example 5) relates to a previously described example (e.g., one of the examples 1-4) wherein the trench extends from a first edge of the semiconductor substrate to an opposing second edge of the semiconductor substrate.

Another example (e.g., example 6) relates to a previously described example (e.g., the example 5) comprising a plurality of trenches.

Another example (e.g., example 7) relates to a previously described example (e.g., one of the examples 1-5) further comprising a supply recess, wherein a width of the supply recess is larger than a width of the trench.

Another example (e.g., example 8) relates to a previously described example (e.g., the example 7) wherein a depth of the supply recess is equal to a depth of the trench.

Another example (e.g., example 9) relates to a previously described example (e.g., one of the examples 7-8) wherein the width of the supply recess is at least 15 µm.

Another example (e.g., example 10) relates to a previously described example (e.g., one of the examples 7-9) wherein the cross-section of the supply recess has a tapered shape.

Another example (e.g., example 11) relates to a previously described example (e.g., one of the examples 1-10) wherein the trench or the plurality of trenches covers at least 5% of the backside of the semiconductor substrate.

Another example (e.g., example 12) relates to a previously described example (e.g., one of the examples 1-11) wherein a thickness of the semiconductor substrate is at most 775 µm.

Another example (e.g., example 13) relates to a previously described example (e.g., one of the examples 1-12) wherein a cross section of the trench has a tapered shape.

An example (e.g., example 14) relates to a heat spreader for a semiconductor device comprising a heat spreading structure attachable to a package structure, wherein the heat spreading structure comprises an opening for conducting a cooling fluid.

Another example (e.g., example 15) relates to a previously described example (e.g., the example 14) wherein the opening has a diameter of at least 500 µm.

Another example (e.g., example 16) relates to a previously described example (e.g., one of the examples 14-15) wherein the opening has a diameter of at most 5 mm.

Another example (e.g., example 17) relates to a previously described example (e.g., one of the examples 14-16) further comprising an interface for attaching a feeding pipe, such that the cooling fluid can flow by use of the feeding pipe through the opening.

Another example (e.g., example 18) relates to a previously described example (e.g., one of the examples 14-17) wherein the heat spreading structure comprises a first opening for feeding the cooling fluid and a second opening for draining the cooling fluid.

Another example (e.g., example 19) relates to a previously described example (e.g., one of the examples 14-18) further comprising a sealing structure for attaching the heat spreading structure to a package structure.

Another example (e.g., example 20) relates to a previously described example (e.g., one of the examples 14-19) wherein the sealing structure comprises solder.

An example (e.g., example 21) relates to a semiconductor package, comprising a first semi-conductor die comprising a plurality of transistors arranged at a front side of the first semi-conductor die and a second semiconductor die, wherein a trench is at least one of located at a surface of a backside of a first semiconductor substrate of the first semiconductor die or located at a second semiconductor substrate of the second semiconductor die, wherein a length of the trench is equal or larger than a lateral dimension of at least one of the first semiconductor substrate or the second semiconductor substrate and wherein the first semiconductor die is attached to the second semiconductor die so that the trench is located between the first semiconductor die and the second semiconductor die.

Another example (e.g., example 22) relates to a previously described example (e.g., example 21) wherein the backside of the first semiconductor die is attached to the front side of the second semiconductor die.

Another example (e.g., example 23) relates to a previously described example (e.g., one of the examples 21-22) wherein the first semiconductor die is a semiconductor die as described above (e.g., according to any of the examples 1 - 13).

Another example (e.g., example 24) relates to a previously described example (e.g., one of the examples 21-23) wherein the second semiconductor die is a semiconductor die as described above (e.g., according to any of the examples 1 - 13).

Another example (e.g., example 25) relates to a previously described example (e.g., one of the examples 21-24) wherein the first semiconductor die or the second semiconductor die comprises a plurality of holes extending through the respective semiconductor substrate and wherein each hole of the plurality of holes faces a part of the trench or a supply recess of the second semiconductor die or the first semiconductor die.

Another example (e.g., example 26) relates to a previously described example (e.g., one of the examples 21-25) wherein a lateral dimension of the first semiconductor die is larger than a lateral dimension of the second semiconductor die, wherein the first semiconductor die comprises the trench formed in the surface of the backside of the semiconductor substrate of the first semiconductor die, further comprising a supply channel arranged beside the second semiconductor die and on top of the first semiconductor die, wherein the supply channel comprises an opening, which faces the trench of the first semiconductor die or a supply recess of the first semiconductor die.

Another example (e.g., example 27) relates to a previously described example (e.g., the example 26) wherein the supply channel is formed in at least one of a mold material and a dielectric material.

Another example (e.g., example 28) relates to a previously described example (e.g., one of the examples 26-27) wherein the supply channel comprises a metal ring embedded in an electrically insulating material.

Another example (e.g., example 29) relates to a previously described example (e.g., one of the examples 21-28) wherein the first semiconductor die is attached to the second semiconductor die by hybrid bonding.

Another example (e.g., example 30) relates to a previously described example (e.g., one of the examples 21-29) wherein a package substrate, wherein the first semiconductor die is attached with the front side of the first semiconductor substrate to the package substrate.

Another example (e.g., example 31) relates to a previously described example (e.g., one of the examples 21-30) further comprising a heat spreader as described above (e.g., according to any of the examples 14 - 20), wherein the heat spreader is attached to the backside of the second semiconductor die or a further semiconductor die located on the second semiconductor die.

Another example (e.g., example 32) relates to a previously described example (e.g., the example 31) wherein the heat spreader is further attached to a package structure.

Another example (e.g., example 33) relates to a previously described example (e.g., one of the examples 31-32) wherein the heat spreader is attached to the backside of the second semiconductor or the further semiconductor die by a thermal backside interface material, wherein the thermal backside interface material contacts the backside of the second semi-conductor die or the further semiconductor die with the heat spreader.

Another example (e.g., example 34) relates to a previously described example (e.g., one of the examples 31-33) further comprising a sealing interface material, wherein the sealing interface material contacts two opposing sides of the semiconductor package with the heat spreader.

An example (e.g., example 35) relates to a semiconductor package as described above (e.g., according to any of the examples 21 - 34); a package substrate, wherein the first semiconductor die or the second semiconductor die is attached with the respective front side of the first semiconductor substrate or the second semiconductor substrate to the package structure; and a heat spreader as described above (e.g., according to any of the examples 14- 20) attached to the package structure.

Another example (e.g., example 36) relates to a previously described example (e.g., the example 35) wherein the package structure comprises a metallic conduct structure on a front side of the package structure facing the semiconductor package and the heat spreader.

Another example (e.g., example 37) relates to a previously described example (e.g., the example 36) wherein the heat spreader is attached to the metallic conduct structure of the package structure by use of a sealing structure.

Another example (e.g., example 38) relates to a previously described example (e.g., one of the examples 35-37) further comprising a semiconductor die contact solder structure for contacting the first semiconductor die or the second semiconductor die with the package structure; an underfill to underfill the contact structure; and a sealing structure covering an edge of the underfill structure.

Another example (e.g., example 39) relates to a previously described example (e.g., the example 38) wherein the sealing structure is attached to the metallic conduct structure.

Another example (e.g., example 40) relates to a previously described example (e.g., one of the examples 35-39) further comprising a thermal backside interface material, wherein the thermal backside interface material contacts a backside of the semiconductor package with the heat spreader.

Another example (e.g., example 41) relates to a previously described example (e.g., one of the examples 35-40) further comprising a sealing interface material, wherein the sealing interface materials contacts two opposing sides of the semiconductor package with the heat spreader.

Another example (e.g., example 42) relates to a previously described example (e.g., the example 41) wherein the sealing interface material and the heat spreader form a first cavity and a second cavity besides the semiconductor package; wherein the first cavity is for feeding a cooling fluid and the second cavity is for draining the cooling fluid, such that the cooling fluid flows through a first opening of the heat spreader in the first cavity, through the trench in the second cavity and through a second opening of the heat spreader out of the second cavity.

An example (e.g., example 43) relates to a method for forming a semiconductor die, comprising forming a plurality of transistors arranged at a front side of a semiconductor substrate; and forming a trench extending from a backside of the semiconductor substrate into the semiconductor substrate, wherein a length of the trench is equal or larger than a lateral dimension of the semiconductor substrate.

Another example (e.g., example 44) relates to a previously described example (e.g., the example 43) wherein the trench is formed by an etching process.

Another example (e.g., example 45) relates to a previously described example (e.g., the example 44) wherein the etching process is an anisotropic etching process.

An example (e.g., example 46) relates to a method for forming a semiconductor package, comprising forming a first semiconductor die comprising a plurality of transistors arranged at a front side of the first semiconductor die; and forming a trench in a surface of a backside of a first semiconductor substrate of the first semiconductor die or a second semiconductor substrate of a second semiconductor die, wherein a length of the trench is equal or larger than a lateral dimension of the first semi-conductor substrate or the second semiconductor substrate; and attaching the first semiconductor die to the second semiconductor die so that the trench is located between the first semiconductor die and the second semiconductor die.

Another example (e.g., example 47) relates to a previously described example (e.g., the example 46) wherein attaching the first semiconductor die to the second semiconductor die comprises hybrid bonding.

Another example (e.g., example 48) relates to a previously described example (e.g., one of the examples 46-47) wherein a first semiconductor die’s cross section is larger than a second semiconductor die’s cross section and wherein the first semiconductor die comprises the trench formed in the surface of the backside of the semiconductor substrate of the first semiconductor die; further comprising, arranging a supply channel besides the second semi-conductor die and on top of the first semiconductor die; wherein the supply channel comprises an opening, which faces the trench of the first semiconductor die.

An example (e.g., example 49) relates to a method for forming a heat spreader for a semi-conductor device; comprising forming a heat spreading structure attachable to a package structure; and forming an opening for conducting a cooling fluid.

Another example (e.g., example 50) relates to a previously described example (e.g., example 49) further comprising forming a sealing structure for attaching the heat spreader to a package structure.

An example (e.g., example 51) relates to a method for forming a semiconductor device, comprising attaching a semiconductor package formed by a method as described above (e.g., according to any of the examples 46 - 48) to a package structure and attaching a heat spreader formed by a method as described above (e.g., according to any of the examples 49-50) to the package structure.

Another example (e.g., example 52) relates to a previously described example (e.g., example 51) further comprising forming a metallic conduct structure on a front side of the package structure facing the semiconductor package and the heat spreader; and wherein the heat spreader is attached to the metallic interface.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A semiconductor die, comprising:
a plurality of transistors arranged at a front side of a semiconductor substrate; and
a trench extending from a backside of the semiconductor substrate into the semiconductor substrate, wherein a length of the trench is equal or larger than a lateral dimension of the semiconductor substrate.

2. The semiconductor die according to claim 1, wherein
a width of the trench is at least 10 µm.

3. The semiconductor die according to claim 1, wherein
a depth of the trench is at least 10 µm.

4. The semiconductor die according to claim 1, wherein
the trench extends in a meandering pattern along the backside of the semiconductor substrate.

5. The semiconductor die according to claim 1, wherein
the trench extends from a first edge of the semiconductor substrate to an opposing second edge of the semiconductor substrate.

6. The semiconductor die according to claim 5, comprising
a plurality of trenches.

7. The semiconductor die according to claim 1, further comprising
a supply recess, wherein a width of the supply recess is larger than a width of the trench.

8. The semiconductor die according to claim 7, wherein
a depth of the supply recess is equal to a depth of the trench.

9. The semiconductor die according to claim 1, wherein
the trench or the plurality of trenches covers at least 5% of the backside of the semiconductor substrate.

10. A heat spreader for a semiconductor device, comprising
a heat spreading structure attachable to a package structure, wherein the heat spreading structure comprises an opening for conducting a cooling fluid.

11. A semiconductor package, comprising:
a first semiconductor die comprising a plurality of transistors arranged at a front side of the first semiconductor die; and
a second semiconductor die; wherein
a trench is at least one of located at a surface of a backside of a first semiconductor substrate of the first semiconductor die or located at a second semiconductor substrate of the second semiconductor die, wherein a length of the trench is equal or larger than a lateral dimension of at least one of the first semiconductor substrate or the second semiconductor substrate; and wherein
the first semiconductor die is attached to the second semiconductor die so that the trench is located between the first semiconductor die and the second semiconductor die.

12. The semiconductor package according to claim 11, wherein
the backside of the first semiconductor die is attached to the front side of the second semiconductor die.

13. The semiconductor package according to claim 11, wherein
the first semiconductor die is a semiconductor die according to claim 1.

14. The semiconductor package according to claim 11, wherein
the second semiconductor die is a semiconductor die according to claim 1.

15. The semiconductor package according to claim 11, wherein
the first semiconductor die or the second semiconductor die comprises a plurality of holes extending through the respective semiconductor substrate and wherein each hole of the plurality of holes faces a part of the trench or a supply recess of the second semiconductor die or the first semiconductor die.

16. The semiconductor package according to claim 11, wherein
a lateral dimension of the first semiconductor die is larger than a lateral dimension of the second semiconductor die, wherein the first semiconductor die comprises the trench formed in the surface of the backside of the semiconductor substrate of the first semiconductor die, further comprising
a supply channel arranged beside the second semiconductor die and on top of the first semiconductor die, wherein
the supply channel comprises an opening, which faces the trench of the first semiconductor die or a supply recess of the first semiconductor die.

17. The semiconductor package according to claim 16, wherein
the supply channel is formed in at least one of a mold material and a dielectric material.

18. The semiconductor package according to claim 11, wherein
the first semiconductor die is attached to the second semiconductor die by hybrid bonding.

19. The semiconductor package according to claim 11, further comprising
a package substrate, wherein
the first semiconductor die is attached with the front side of the first semiconductor substrate to the package substrate.

20. The semiconductor package according to claim 11, further comprising
a heat spreading structure attachable to the package structure, wherein the heat spreading structure comprises an opening for conducting a cooling fluid., wherein
the heat spreader is attached to the backside of the second semiconductor die or a further semiconductor die located on the second semiconductor die.

21. The semiconductor package according to claim 20, wherein
the heat spreader is further attached to a package structure.

22. The semiconductor package according to claim 20, wherein
the heat spreader is attached to the backside of the second semiconductor or the further semiconductor die by a thermal backside interface material, wherein the thermal backside interface material contacts the backside of the second semiconductor die or the further semiconductor die with the heat spreader.

23. The semiconductor package according to claim 20, further comprising
a sealing interface material, wherein the sealing interface material contacts two opposing sides of the semiconductor package with the heat spreader.

24. A method for forming a semiconductor die, comprising:
forming a plurality of transistors arranged at a front side of a semiconductor substrate; and
forming a trench extending from a backside of the semiconductor substrate into the semiconductor substrate, wherein a length of the trench is equal or larger than a lateral dimension of the semiconductor substrate.

25. The method according to claim 24, wherein
the trench is formed by an etching process.
